(19) United States
(12) Patent Application Publication
(10) Pub. No.: US 2024/0315080 A1
(43) Pub. Date: Sep. 19, 2024

(54) DISPLAY DEVICE

(71) Applicant: SHARP KABUSHIKI KAISHA, Sakai City, Osaka (JP)

(72) Inventors: TOHRU SONODA, Sakai City, Osaka (JP); JUNYA SHIMADA, Sakai City, Osaka (JP); MASAHIRO INUZUKA, Sakai City, Osaka (JP); Tsuyoshi INOUE, Sakai City, Osaka (JP)

(21) Appl. No.: 18/276,453

(22) PCT Filed: Feb. 15, 2021
(86) PCT No.: PCT/JP2021/005426

§ 371 Date: Aug. 9, 2023

(51) Int. Cl. H10K 59/121; H10K 59/124; H10K 59/80

(52) U.S. Cl. CPC H10K 59/1216; H10K 59/1213; H10K 59/124; H10K 59/871

(57) ABSTRACT

A display device includes the following: a display region with a plurality of pixels provided in matrix; and a plurality of capacitors provided in a frame region located around the display region, and electrically floating.

### TECHNICAL FIELD

The present disclosure relates to a display device.

### BACKGROUND ART

In the organic EL panel in Patent Literature 1, a wire electrode has, near an organic EL element, an end with its end's corner rounded, i.e., an R-shape, in plan view. Patent Literature 1 describes that since the end is rounded, i.e., an R-shape, so that electric charge can easily concentrate, electric charge does not concentrate on the end even if the wire electrode becomes electrostatically charged, and thus, charge flow from the wire electrode into the organic EL element seems to be able to be prevented.

### CITATION LIST

### Patent Literature

Patent Literature 1: International Publication No. 2011/108113

### SUMMARY OF INVENTION

### Technical Problem

However, the organic EL panel in Patent Literature 1 cannot prevent electric charge that flows into the organic EL element via the substrate's surface without via the wire electrode. Furthermore, it is not possible to identify which location in the organic EL panel such electric charge flows into easily from. One aspect of the present disclosure provides a display device that facilitates identifying a location into which electric charge flows easily, and that can thus prevent degradation in image's display quality resulting from the flowed electric charge.

### Solution to Problem

A display device according to one aspect of the present disclosure includes the following: a display region with a plurality of pixels provided in matrix; and a plurality of capacitors provided in a frame region located around the display region, and electrically floating.

### BRIEF DESCRIPTION OF DRAWINGS

FIG. 1 is a plan view of the schematic configuration of a display device according to an embodiment.

FIG. 2 is a plan view of the display device according to the embodiment and schematically illustrates its charge accumulating unit and the display region near the charge accumulating unit.

FIG. 3 is a sectional view taken along line A1-A2 in FIG. 2.

FIG. 4 is a sectional view of the schematic configuration of a light-emitting element of the display device according to the embodiment.

FIG. 5 is a plan view of the configuration of a mother substrate according to the embodiment.

FIG. 6 is a plan view of the schematic configuration of a mask according to the embodiment.

FIG. 7 is a side view of the schematic configuration of an evaporation device according to the embodiment.

FIG. 8 is a schematic enlarged view of a region near the ends of the mask and mother substrate illustrated in FIG. 7.

FIG. 9 illustrates the mother substrate according to the embodiment under removal from the mask after an evaporation step.

FIG. 10 shows the amount of electric charge accumulated in each of a plurality of capacitors of the display device according to the embodiment.

FIG. 11 is an enlarged plan view of part of a mask sheet according to the embodiment.

FIG. 12 illustrates the mother substrate under patterning with a common metal mask in the process of manufacturing the display device according to the embodiment.

FIG. 13 illustrates the mother substrate according to the embodiment with spacers formed, under patterning with the mask.

FIG. 14 is a sectional view of the schematic configuration of the display device according to a first modification of the embodiment.

FIG. 15 is a plan view of the display device according to a second modification of the embodiment and schematically illustrates its charge accumulating unit and the display region near the charge accumulating unit.

FIG. 16 is a plan view of the schematic configuration of the display device according to a third modification of the embodiment.

FIG. 17 is a plan view of the schematic configuration of the display device according to a fourth modification of the embodiment.

FIG. 18 is a sectional view taken along line B1-B2 in FIG. 17.

### DESCRIPTION OF EMBODIMENT

### Embodiment

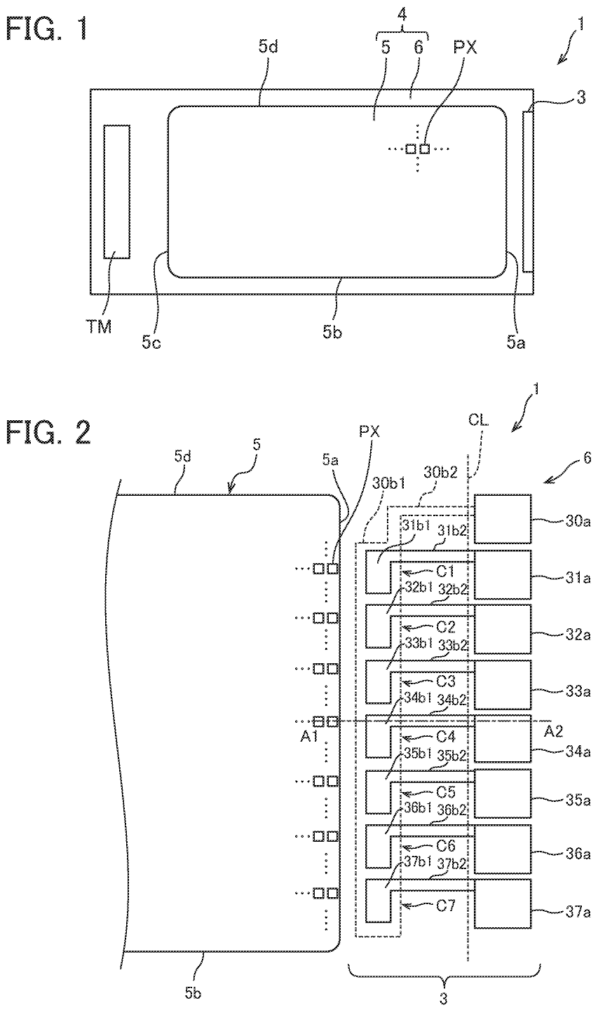

FIG. 1 is a plan view of the schematic configuration of a display device 1 according to an embodiment. The display device 1 is, for instance, an electronic device, such as a portable terminal, that can display an image. A possible example of the display device 1 is a smartphone.

The display device 1 includes, for instance, a display panel 4 and a casing (not shown) covering the side and backside of the display panel 4. The display panel 4 includes a display region 5 with a plurality of pixels PX provided in matrix, and a frame region 6 in the form of a bezel surrounding the display region 5. The display panel 4 needs to be a display panel that can display an image; various display panels can be used, including a liquid-crystal display panel, an organic light-emitting diode (OLED) display panel and a quantum-dot light-emitting diode (QLED) display panel. It is noted that the display panel 4 will be described as an OLED display panel by way of example in this embodiment.

The display region 5 is a region for image display. The plurality of pixels PX provided in the display region 5 emit light, thus displaying an image onto the display panel 4. For instance, the plurality of pixels PX include a red pixel that emits red light, a green pixel that emits green light, and a blue pixel that emits blue light.

In plan view, the display region 5 is in the form of, for instance, a rectangle with its four corners curved (rounded). The display region 5 has, for instance, a first side 5a, a second side 5b, a third side 5c and a fourth side 5d, which constitute an end defining its outer shape. For instance, the first side 5a and the third side 5c are shorter sides facing each other. For instance, the second side 5b and the fourth side 5d are longer sides facing each other. It is noted that the shape of the display region 5 in plan view is not limited to the foregoing shape; the display region 5 may take any other shape.

The frame region 6 is not provided with a plurality of pixels PX that emit light, but is provided with, but not limited to, a wire or electrode connected to an electrode or wire provided in the display region 5.

In the frame region 6, a terminal section TM with a plurality of terminals provided is provided along the third side 5c. In the terminal section TM is, but not limited to, a drive circuit mounted for supplying various signals to the display region 5. Further, each of the plurality of terminals mounted in the terminal section TM is connected to a routed wire provided in the frame region 6. For instance, the routed wire is connected, at its one end, to an electrode or wire provided in the display region 5, is routed from the display region 5 to the frame region 6 from its one end to the other end and is connected, at the other end, to any of the plurality of terminals provided in the terminal section TM.

Here, when the display region 5 undergoes patterning with a mask as described later on, for instance, the mask comes into contact with the frame region 6, thus possibly causing electric charge accumulated in the mask to flow into the frame region 6, or when the mother substrate being in contact with the mask undergoes removal after the patterning, electrification resulting from the removal, or other things occurs, thus possibly causing the electric charge to flow into the frame region 6.

Accordingly, the display device 1 according to this embodiment includes, in the frame region 6, at least one charge accumulating unit 3 with a plurality of capacitors provided. The charge accumulating unit 3 captures and accumulates electric charge that moves from the frame region 6 toward the display region 5, to thus prevent electric charge from flowing into the display region 5. In addition, as described later on, a location into which electric charge easily flows can be identified as well, by inspecting the amount of electric charge accumulated in each of the plurality of capacitors provided in the charge accumulating unit 3. This can prevent degradation in image's display quality resulting from charge flow into the display region 5.

In the example illustrated in FIG. 1 for instance, a single charge accumulating unit 3 is provided along the first side 5a at the end of the display region 5. For instance, the charge accumulating unit 3 is provided in the frame region 6 so as to face the first side 5a, which is a shorter side opposite to the third side 5c, provided so as to face the terminal section TM.

As described above, the charge accumulating unit 3 is provided along the first side 5a, which is a shorter side of the display region 5 facing the third side 5c, provided near the terminal section TM, and the charge accumulating unit 3 can be thus provided away from the terminal section TM. This can accumulate electric charge in the plurality of capacitors, provided in the charge accumulating unit 3, while minimizing the effect of electric charge exerted from the drive circuit connected to the terminal section TM, or from other components. Consequently, electric charge can more accurately accumulate in the plurality of capacitors, provided in the charge accumulating unit 3, and thus, degradation in image's display quality resulting from charge flow into the display region 5 can be prevented with more certainty.

FIG. 2 is a plan view of the display device 1 according to the embodiment and schematically illustrates the charge accumulating unit 3 and the display region 5 near the charge accumulating unit 3.

The charge accumulating unit 3 includes the following: a plurality of capacitors C1 to C7; a plurality of electrode pads 31a to 37a respectively connected to the plurality of capacitors C1 to C7; and an electrode pad 30a connected to each of the plurality of capacitors C1 to C7. The electrode pad 30a is connected to one electrode of each of the plurality of capacitors C1 to C7. The plurality of electrode pads 31a to 37a are connected to the respective other electrodes of the plurality of capacitors C1 to C7. It is noted that the number of capacitors C1 to C7 and the number of electrode pads 30a to 37a can be changed freely.

The capacitors C1 to C7 are provided along the first side 5a, which, as earlier described, is a shorter side of the display region 5 facing the third side 5c provided near the terminal section TM (see FIG. 1), and is away from the terminal section TM.

For instance, each of the capacitors C1 to C7 capturers and accumulates, but not limited to, electric charge, such as static electricity, generated in the frame region 6, and electric charge flowed from the outside, such as a mask. This prevents electric charge from flowing from the frame region 6 into the display region 5.

The electrode pad 30a and the electrode pads 31a to 37a are electrically connected to the plurality of capacitors C1 to C7 and are terminals for an inspection device that inspects the amount of electric charge, or for an operator to inspect the amount of electric charge accumulated in each of the plurality of capacitors C1 to C7.

For instance, the plurality of capacitors C to C7 are arranged sequentially along the first side 5a, which is a shorter side at the end of the display region 5. That is, each of the capacitors C1 to C7 is provided so as to be adjacent to the plurality of pixels PX arranged along the first side 5a, which is the end of the display region 5. Thus, the capacitors C1 to C7 capture and accumulate electric charge that moves from the frame region 6 toward the first side 5a of the display region 5.

For instance, the capacitor C1 includes the following: a lower electrode (one electrode) 30b1 provided in a relatively lower layer; and an upper electrode (the other electrode) 31b1 provided in a relatively upper layer than the lower electrode 30b1, and overlapping the lower electrode 30b1. The capacitor C2 includes the following: the lower electrode (one electrode) 30b1 provided in a relatively lower layer; and an upper electrode (the other electrode) 32b1 provided in a relatively upper layer than the lower electrode 30b1, and overlapping the lower electrode 30b1. The capacitor C3 includes the following: the lower electrode (one electrode) 30b1 provided in a relatively lower layer; and an upper electrode (the other electrode) 33b1 provided in a relatively upper layer than the lower electrode 30b1, and overlapping the lower electrode 30b1.

The capacitor C4 includes the following: the lower electrode (one electrode) 30b1 provided in a relatively lower layer; and an upper electrode (the other electrode) 34b1 provided in a relatively upper layer than the lower electrode 30b1, and overlapping the lower electrode 30b1. The capacitor C5 includes the following: the lower electrode (one electrode) 30b1 provided in a relatively lower layer; and an upper electrode (the other electrode) 35b1 provided in a relatively upper layer than the lower electrode 30b1, and overlapping the lower electrode 30b1. The capacitor C6 includes the following: the lower electrode (one electrode) 30b1 provided in a relatively lower layer; and an upper electrode (the other electrode) 36b1 provided in a relatively upper layer than the lower electrode 30b1, and overlapping the lower electrode 30b1. The capacitor C7 includes the following: the lower electrode (one electrode) 30b1 provided in a relatively lower layer; and an upper electrode (the other electrode) 37b1 provided in a relatively upper layer than the lower electrode 30b1, and overlapping the lower electrode 30b1.

For instance, the lower electrode 30b1 is a common electrode continuous throughout the plurality of capacitors C1 to C7. The lower electrode 30b1 is connected to the electrode pad 30a via a connection wire 30b2. The connection wire 30b2 has one end connected to the lower electrode 30b1, and the other end connected to the electrode pad 30a.

For instance, the lower electrode 30b1 and the connection wire 30b2 contain the same material. The lower electrode 30b1 and the connection wire 30b2 are formed in the same process step using the same material. For instance, the lower electrode 30b1 and the connection wire 30b2 are formed integrally to be thus electrically connected together. Further for instance, the connection wire 30b2 and the electrode pad 30a are electrically connected together via a contact hole formed in an insulating layer provided between them.

For instance, the upper electrodes 31b1 to 37b1 are spaced and separated from each other.

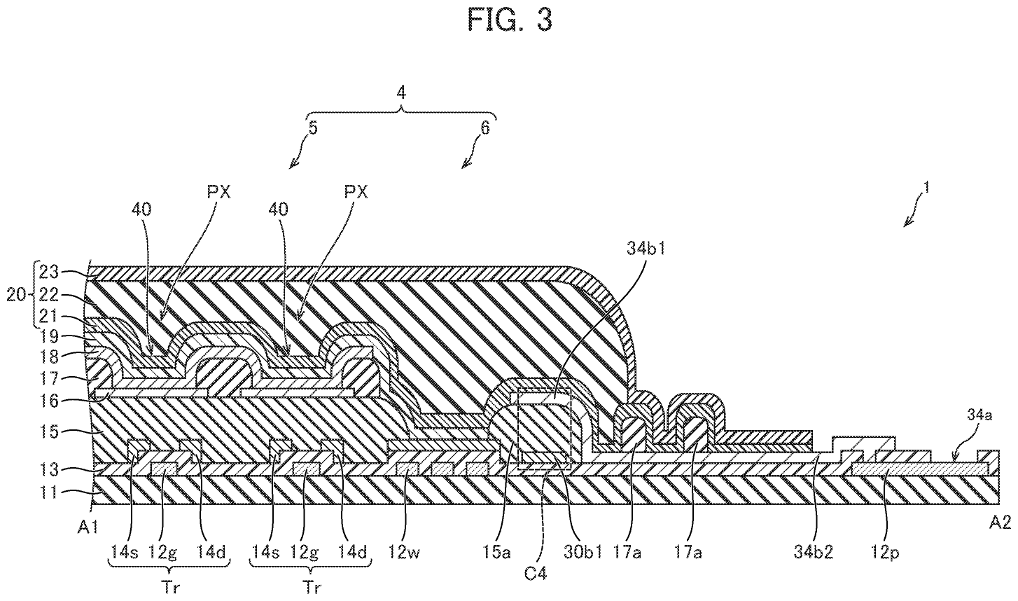

The upper electrode 31b1 is connected to the electrode pad 31a via a connection wire 31b2. The connection wire 31b2 has one end connected to the upper electrode 31b1, and the other end connected to the electrode pad 31a. For instance, the upper electrode 31b1 and the connection wire 31b2 contain the same material. The upper electrode 31b1 and the connection wire 31b2 are formed in the same process step using the same material. For instance, the upper electrode 31b1 and the connection wire 31b2 are formed integrally to be thus electrically connected together. Further for instance, the connection wire 31b2 and the electrode pad 31a are electrically connected together via a contact hole formed in an insulating layer (e.g., a gate insulating layer 13 illustrated in FIG. 3) provided between them.

The upper electrode 32b1 is connected to the electrode pad 32a via a connection wire 32b2. The connection wire 32b2 has one end connected to the upper electrode 32b1, and the other end connected to the electrode pad 32a. For instance, the upper electrode 32b1 and the connection wire 32b2 contain the same material. The upper electrode 32b1 and the connection wire 32b2 are formed in the same process step using the same material. For instance, the upper electrode 32b1 and the connection wire 32b2 are formed integrally to be thus electrically connected together. Further for instance, the connection wire 32b2 and the electrode pad 32a are electrically connected together via a contact hole formed in an insulating layer (e.g., the gate insulating layer 13 illustrated in FIG. 3) provided between them.

The upper electrode 33b1 is connected to the electrode pad 33a via a connection wire 33b2. The connection wire 33b2 has one end connected to the upper electrode 33b1, and the other end connected to the electrode pad 33a. For instance, the upper electrode 33b1 and the connection wire 33b2 contain the same material. The upper electrode 33b1 and the connection wire 33b2 are formed in the same process step using the same material. For instance, the upper electrode 33b1 and the connection wire 33b2 are formed integrally to be thus electrically connected together. Further for instance, the connection wire 33b2 and the electrode pad 33a are electrically connected together via a contact hole formed in an insulating layer (e.g., the gate insulating layer 13 illustrated in FIG. 3) provided between them.

The upper electrode 34b1 is connected to the electrode pad 34a via a connection wire 34b2. The connection wire 34b2 has one end connected to the upper electrode 34b1, and the other end connected to the electrode pad 34a. For instance, the upper electrode 34b1 and the connection wire 34b2 contain the same material. The upper electrode 34b1 and the connection wire 34b2 are formed in the same process step using the same material. For instance, the upper electrode 34b1 and the connection wire 34b2 are formed integrally to be thus electrically connected together. Further for instance, the connection wire 34b2 and the electrode pad 34a are electrically connected together via a contact hole formed in an insulating layer (e.g., the gate insulating layer 13 illustrated in FIG. 3) provided between them.

The upper electrode 35b1 is connected to the electrode pad 35a via a connection wire 35b2. The connection wire 35b2 has one end connected to the upper electrode 35b1, and the other end connected to the electrode pad 35a. For instance, the upper electrode 35b1 and the connection wire 35b2 contain the same material. The upper electrode 35b1 and the connection wire 35b2 are formed in the same process step using the same material. For instance, the upper electrode 35b1 and the connection wire 35b2 are formed integrally to be thus electrically connected together. Further for instance, the connection wire 35b2 and the electrode pad 35a are electrically connected together via a contact hole formed in an insulating layer (e.g., the gate insulating layer 13 illustrated in FIG. 3) provided between them.

The upper electrode 36b1 is connected to the electrode pad 36a via a connection wire 36b2. The connection wire 36b2 has one end connected to the upper electrode 36b1, and the other end connected to the electrode pad 36a. For instance, the upper electrode 36b1 and the connection wire 36b2 contain the same material. The upper electrode 36b1 and the connection wire 36b2 are formed in the same process step using the same material. For instance, the upper electrode 36b1 and the connection wire 36b2 are formed integrally to be thus electrically connected together. Further for instance, the connection wire 36b2 and the electrode pad 36a are electrically connected together via a contact hole formed in an insulating layer (e.g., the gate insulating layer 13 illustrated in FIG. 3) provided between them.

The upper electrode 37b1 is connected to the electrode pad 37a via a connection wire 37b2. The connection wire 37b2 has one end connected to the upper electrode 37b1, and the other end connected to the electrode pad 37a. For instance, the upper electrode 37b1 and the connection wire 37b2 contain the same material. The upper electrode 37b1 and the connection wire 37b2 are formed in the same process step using the same material. For instance, the upper electrode 37b1 and the connection wire 37b2 are formed integrally to be thus electrically connected together. Further for instance, the connection wire 37b2 and the electrode pad 37a are electrically connected together via a contact hole formed in an insulating layer (e.g., the gate insulating layer 13 illustrated in FIG. 3) provided between them.

As described above, the display device 1 according to this embodiment includes the following: the display region 5 with the plurality of pixels PX provided in matrix; and the plurality of capacitors C1 to C7 provided in the frame region 6 located around the display region 5, and electrically floating. Further, the connection wires 30b2 to 37b2 of the display device 1 connected to the capacitors C1 to C7, and the electrode pads 30a to 37a of the same connected to the connection wires 30b2 to 37b2 are also electrically floating.

Here, the word “electrically floating” means that the capacitors C1 to C7, the connection wires 30b2 to 37b2 connected to the capacitors C1 to C7, and the electrode pads 30a to 37a connected to the connection wires 30b2 to 37b2 are, for instance, all not connected to, but not limited to, a routed wire connected to an electrode or wire provided in the display region 5 and are all provided in the form of an island separated away from any of the wires and electrodes.

Further, the capacitors C1 to C7, which are electrically floating, can accumulate electric charge different from electric charge necessary for the display device 1 to display an image, unlike a capacitor (e.g., a capacitor included in a pixel circuit that drives a corresponding one of the pixels PX, and provided in the display region 5) that accumulates electric charge necessary for the display device 1 to display an image.

As described above, the electrically floating capacitors C1 to C7 of the display device 1 can capture and accumulate electric charge that flows from the frame region 6 into the display region 5. This can prevent a property deficiency (ON-and-OFF threshold voltage shift) in a thin-film transistor Tr (see FIG. 3), which is provided in each pixel PX, that results from the flowed electric charge, thereby improving the reliability of the display device 1.

Further, unlike the organic EL panel in Patent Literature 1, the display device 1, which includes the plurality of electrically floating capacitors C1 to C7 in the frame region 6 located around the display region 5, facilitates capturing electric charge that flows the surface of the frame region 6 of the display device 1 into the display region 5 of the same by using the plurality of capacitors C1 to C7 without via a wire extending from the frame region 6 to the inside of the display region 5. This can prevent a property deficiency in the thin-film transistor Tr (see FIG. 3), thereby improving the reliability of the display device 1.

Furthermore, the display device 1, which includes the electrically floating capacitors C1 to C7, can accumulate electric charge in each of the capacitors C1 to C7 individually. This facilitates identifying a location into which electric charge flows easily in a process step for manufacturing the display device 1, such as an evaporation step, thereby facilitating avoiding a property deficiency in the thin-film transistor Tr (see FIG. 3) that drives the pixel PX located near a location into which electric charge flows easily. Consequently, the display device 1 with degradation in image's display quality due to flowed electric charge being prevented can be achieved.

The plurality of capacitors C1 to C7 are a common electrode with their individual lower electrodes 30b1 are coupled to each other. This enables the lower electrodes to capture, without fail, electric charge that flows from the frame region 6 into the display region 5 when compared with an instance where the lower electrodes are separated from each other and thus have gaps therebetween, and degradation in image's display quality can be thus prevented with more certainty. Further, the plurality of capacitors C1 to C7 are individually provided such that their upper electrodes 31b1 to 37b1 are separated away from each other. This enables the plurality of capacitors C1 to C7 to each accumulate electric charge individually, thereby facilitating identifying a location into which electric charge flows easily. Consequently, a property deficiency in the thin-film transistor Tr (see FIG. 3) that drives the pixel PX located near a location into which electric charge flows easily can be avoided easily.

That is, the plurality of capacitors C1 to C7, which have their ends (lower electrodes 30b1) coupled together and their other ends (upper electrodes 31b1 to 37b1) separated from each other, can capture electric charge without fail and enable a location into which electric charge easily flows to be identified easily.

Furthermore, the electrodes (lower electrodes 30b1) of the plurality of capacitors C1 to C7, which are coupled together, have their potentials that are common in the plurality of capacitors C1 to C7. This can precisely detect the amount of electric charge accumulated in each capacitor by using a corresponding one of the potential differences of the plurality of capacitors C1 to C7.

Further, the display device 1 includes, in the charge accumulating unit 3, the plurality of electrode pads 30a to 37a respectively connected to the plurality of capacitors C1 to C7. This enables the inspection device or operator to inspect, in the process of manufacturing the display device 1, the amount of electric charge accumulated in the plurality of individual capacitors C1 to C7 via the plurality of electrode pads 30a to 37a. Consequently, the display device 1 with degradation in image's display quality prevented can be achieved.

In addition, leaving the plurality of electrode pads 30a to 37a as they are in the display device 1 even after the completion of the display device 1 enables the inspection device or operator to inspect, even after the completion of the display device 1, the amount of electric charge accumulated in the plurality of individual capacitors C1 to C7 via the plurality of electrode pads 30a to 37a. This can continuously monitor and prevent degradation in image's display quality even after the completion of the display device 1, depending on the use conditions of the display device 1.

It is noted that as illustrated in FIG. 2, the display panel 4 of the display device 1 may be configured, when cut out of the mother substrate into a piece, such that the electrode pads 30a to 37a are cut away along a cutting line CL (broken line in FIG. 2), intersecting with each of the connection wires 30b to 37b, to thus no longer exist.

In this case, the charge accumulating unit 3 includes the plurality of capacitors C1 to C7 and part of each of the connection wires 30b2 to 37b2 (portions close to the capacitors C1 to C7 from the cutting line CL) and does not include the electrode pads 30a to 37a.

This can prevent degradation in image's display quality resulting from electrical noise received from the electrode pads 30a to 37a after the display panel 4 is processed into a piece and after the display device 1 is completed.

It is noted that electric charge that transmits from the frame region 6 to the display region 5 can be captured and accumulated by the capacitors C1 to C7 even when the electrode pads 30a to 37a are removed from the display panel 4. That is, even in a configuration where the display device 1 includes the capacitors C1 to C7 and does not include the electrode pads 30a to 37a connected to the capacitors C1 to C7, the display device 1 can prevent degradation in image's display quality in the display region 5 by capturing, using the capacitors C1 to C7, electric charge that transmits from the frame region 6 to the display region 5, continuously even after the completion of the display device 1.

FIG. 3 is a sectional view taken along line A1-A2 in FIG. 2. It is noted that the sectional shape of the capacitor C4 will be herein described among the plurality of capacitors C1 to C7, and that the sectional shapes of the other capacitors C1 to C3 and C5 to C7, which are the same as that of the capacitor C4, will not be described.

For instance, the display device 1 includes the following: a support substrate 11; a gate electrode 12g, a routed wire 12w and a conductive layer 12p; a gate insulating layer 13; a source electrode 14s, a drain electrode 14d and the lower electrode 30b1; an interlayer insulating layer 15 and an insulating portion 15a; a first electrode 16, the upper electrode 34b1 and the connection wire 34b2; a pixel bank 17 and a frame-shaped bank 17a; an electroluminescence (EL) layer 18; a second electrode 19; and a sealing layer 20.

The gate electrode 12g, the source electrode 14s and the drain electrode 14d constitute the thin-film transistor Tr. The thin-film transistor Tr is provided for each pixel PX.

Further, the capacitor C4 includes the following: the lower electrode 30b1 provided in a relatively lower layer; the upper electrode 34b1 provided in a relatively upper layer than the lower electrode 30b1; and the insulating portion 15a provided between the lower electrode 30b1 and the upper electrode 34b1.

The support substrate 11 is a substrate continuous all over the display panel 4 including the display region 5 and frame region 6. The support substrate 11 is, for instance, a flexible substrate. An example of the flexible substrate may be a substrate of multilayer structure including an organic insulating layer and an inorganic insulating layer. The organic insulating layer contains an organic insulating material, such as polyimide. The inorganic insulating film contains an inorganic insulating material, such as silicon oxide, silicon nitride or silicon oxide nitride. Alternatively, the support substrate 11 may be an inflexible hard substrate containing an inorganic insulating material, such as glass.

The gate electrode 12g, the routed wire 12w and the conductive layer 12p are each formed on the support substrate 11 in the same process step using the same material. The gate electrode 12g, the routed wire 12w and the conductive layer 12p are metal monolayer or multilayer structures containing, for instance, at least one of aluminum, tungsten, molybdenum, tantalum, chromium, titanium and copper, and they can be formed through sputtering or other methods.

The gate electrode 12g is the gate electrode of the thin-film transistor Tr, which is provided for each pixel PX, and is formed in the display region 5 for each thin-film transistor Tr. The gate electrode 12g is connected to a gate line (not shown) that supplies a gate signal to the gate electrode 12g.

The routed wire 12w is a routed wire routed from the display region 5 to the frame region 6, and the wire has one end connected to an electrode or wire within the display region 5, and the other end connected to, but not limited to, another wire, electrode or terminal, such as any of the plurality of terminals provided in the terminal section TM (see FIG. 1).

The conductive layer 12p is formed in a region including the region where the electrode pad 34a is formed. A region of the conductive layer 12p from which the gate insulating layer 13 is exposed is the electrode pad 34a. The conductive layer 12p is formed in the charge accumulating unit 3 (see FIG. 1 and FIG. 2) in the frame region 6. It is noted that conductive layers separated from each other are formed also in regions including the regions where the respective electrode pads 30a to 33a and 35a to 37a (see FIG. 2) are formed, in the same process step using the same material as the conductive layer 12p.

The gate insulating layer 13 is formed, for instance, through CVD using an inorganic insulating material, such as silicon oxide, silicon nitride or silicon oxide nitride. The gate insulating layer 13 covers the gate electrode 12g and the routed wire 12w and is formed on the support substrate 11. The gate insulating layer 13 also covers a region of the conductive layer 12p located around the electrode pad 34a and exposes the surface of the conductive layer 12p without covering the region where the electrode pad 34a is formed. It is noted that the gate insulating layer 13 also exposes the regions where the respective electrode pads 30a to 33a and 35a to 37a (see FIG. 2) are formed without covering the surfaces of the individual conductive layers.

The source electrode 14s, the drain electrode 14d and the lower electrode 30b1 are metal monolayer or multilayer structures containing, for instance, at least one of aluminum, tungsten, molybdenum, tantalum, chromium, titanium and copper, and they can be formed through sputtering or other methods.

The source electrode 14s is the source electrode of the thin-film transistor Tr, which is provided for each pixel PX, and is formed in the display region 5 for each thin-film transistor Tr. The source electrode 14s is connected to a signal line (not shown) that supplies a source signal to the source electrode 14s. The drain electrode 14d is the drain electrode of the thin-film transistor Tr, which is provided for each pixel PX, and is formed in the display region 5 for each thin-film transistor Tr. The drain electrode 14d is connected to the first electrode 16 via a contact hole formed in the interlayer insulating layer 15.

As described above, the thin-film transistor Tr includes the gate electrode 12g, the source electrode 14s and the drain electrode 14d and is provided for each pixel PX. It is noted that although not shown, the thin-film transistor Tr further has a semiconductor layer. The semiconductor layer is provided so as to overlap the gate electrode 12g with an insulating layer interposed therebetween. The semiconductor layer is composed of, for instance, low-temperature polysilicon (LTPS) or oxide semiconductor. The oxide semiconductor contains at least one metal element among In, Ga and Zn.

The lower electrode 30b1 is one of the electrodes of each of the plurality of capacitors C1 to C7 (see FIG. 2) including the capacitor C4, and this electrode is provided in a relatively lower layer. It is noted that the connection wire 30b2 (see FIG. 2) is also formed in the same process step using the same material as the lower electrode 30b1.

As described above, the lower electrode 30b1 for instance, which is one of the electrodes of each of the capacitors C1 to C7 contains the same material and is formed in the same process step as the source electrode 14s and drain electrode 14d of each of the plurality of thin-film transistors Tr. This eliminates the need to separately add a process step for forming the lower electrode 30b1, which is one of the electrodes of each of the capacitors C1 to C7, and can form the capacitors C1 to C7 without increasing the number of process steps.

The interlayer insulating layer 15 and the insulating portion 15a are formed in the same process step using the same material. The interlayer insulating layer 15 and the insulating portion 15a can be formed through photolithography or other methods using an organic insulating material, such as polyimide or acrylic.

The interlayer insulating layer 15 covers the thin-film transistors Tr and is formed on the gate insulating layer 13 in the display region 5. The interlayer insulating layer 15 flattens asperities produced by the thin-film transistors Tr.

The insulating portion 15a is part of each of the plurality of capacitors C1 to C7 (see FIG. 2) including the capacitor C4 and is formed between the lower electrode 30b1 and each of the upper electrodes 31b1 to 37b1 including the upper electrode 34b1. The insulating portion 15a covers the lower electrode 30b1 and is formed on the gate insulating layer 13 in the frame region 6. For instance, the insulating portion 15a is separated away from the interlayer insulating layer 15. The insulating portion 15a extends along the direction where the lower electrode 30b1 extends. For instance, the insulating portion 15a extends along the first side Sa of the display region 5 in plan view.

As described above, for instance, the insulating portion 15a of the capacitors C1 to C7 contains the same material and is formed in the same process step as the interlayer insulating layer 15, which covers the plurality of individual thin-film transistors Tr. This eliminates the need to separately add a process step for forming the insulating portion 15a of the capacitors C1 to C7 and can form the capacitors C1 to C7 without increasing the number of process steps.

Here, if the insulating portion is separated, an electric field concentrates on this separated portion, thereby possibly causing an unexpected short-circuit defect between the upper electrode and lower electrode.

Accordingly, for instance, the insulating portion 15a according to this embodiment is formed continuously across each of the plurality of capacitors C1 to C7 (see FIG. 2) including the capacitor C4.

This can prevent a short circuit between the lower electrode 30b1 and each of the upper electrodes 31b1 to 37b1 in a corresponding one of the plurality of capacitors C1 to C7. Consequently, the plurality of capacitors C1 to C7 can capture electric charge, further without fail.

For instance, the first electrode 16, the upper electrode 34b1 and the connection wire 34b2 are formed in the same process step using the same material. It is noted that for instance, the upper electrode 34b1 and the connection wire 34b2 are formed integrally.

The first electrode 16, the upper electrode 34b1 and the connection wire 34b2 can be, for instance, a stack of a metal reflective layer and a transparent conductive layer. The metal reflective layer contains, but not limited to, aluminum, copper, gold or silver. The transparent conductive layer contains, for instance, a transparent conductive material, such as indium tin oxide (ITO), indium zinc oxide (IZO), zinc oxide (ZnO), aluminum-doped zinc oxide (AZO) or gallium-doped zinc oxide (GZO). The metal reflective layer and the transparent conductive layer can be formed through, but not limited to, sputtering or evaporation.

The first electrode 16 is formed on the interlayer insulating layer 15 for each pixel PX. The first electrode 16 is connected to the drain electrode 14d of the thin-film transistor Tr via a contact hole formed in the interlayer insulating layer 15. The first electrode 16 drives the pixel PX in accordance with a switching operation of the thin-film transistor Tr. For instance, the first electrode 16 is an anode and reflective electrode. It is noted that the first electrode 16 may be a cathode rather than an anode.

The upper electrode 34b1 and the connection wire 34b2 are formed in the frame region 6. The upper electrode 34b1 is the other electrode of the capacitor C4 provided in a relatively upper layer than the lower electrode 30b1. The upper electrode 34b1 is formed on the insulating portion 15a. The connection wire 34b2 has, on the insulating portion 15a, one end connected to the upper electrode 34b1, is provided, until its other end, on the gate insulating layer 13 in the frame region 6 and has the other end electrically connected to the conductive layer 12p via a contact hole formed in the gate insulating layer 13 covering the conductive layer 12p.

Further, the upper electrodes 31b1 to 33b1 and 35b1 to 37b1 (see FIG. 2) and the connection wires 31b2 to 33b2 and 35b2 to 37b2 (see FIG. 2) are also formed in the same process step using the same material as the upper electrode 34b1 and connection wire 34b2. The upper electrodes 31b1 to 33b1 and 35b1 to 37b1 (see FIG. 2) are formed in a manner similar to that in the foregoing upper electrode 34b1. Further, the connection wires 31b2 to 33b2 and 35b2 to 37b2 (see FIG. 2) are formed in a manner similar to that in the foregoing connection wire 34b2.

As described above, the upper electrodes 31b1 to 37b1 of the respective capacitors C1 to C7 contain the same material and are formed in the same process step as the first electrode 16. This eliminates the need to separately add a process step for forming the upper electrodes 31b1 to 37b1, which are the other electrodes of the respective capacitors C1 to C7, and can form the capacitors C1 to C7 without increasing the number of process steps.

The pixel bank 17 and the frame-shaped bank 17a are formed in the same process step using the same material. The pixel bank 17 and the frame-shaped bank 17a are formed through, but not limited to, photolithography using an organic insulating material, such as polyimide or acrylic.

The pixel bank 17 is formed on the interlayer insulating layer 15 in the display region 5.

The pixel bank 17 is formed between the pixels PX and sections the individual pixels PX. The pixel bank 17 may cover the end of the first electrode 16.

It is noted that a spacer may be further provided on the pixel bank 17. Such a spacer that is brought into contact with a mask in an evaporation step avoids a patterning layer patterned for each pixel PX from coming into contact with the mask on the pixel bank. The spacer can be formed through, but not limited to, photolithography using an organic photosensitive insulating material, such as polyimide or acrylic.

The frame-shaped bank 17a is formed on the gate insulating layer 13 in the frame region 6 so as to intersect with the connection wire 30b2 and connection wires 31b2 to 37b2 (see FIG. 2) in plan view and surrounds the display region 5. The frame-shaped bank 17a functions as a bank in forming an organic layer 22 of the sealing layer 20. Multiple frame-shaped banks 17a may be formed. In the example illustrated in FIG. 3, two frame-shaped banks 17a are formed, and the display region 5 is surrounded twofold by the two frame-shaped banks 17a.

Further, for instance, the frame-shaped bank 17a extends outside the capacitors C1 to C7 (FIG. 2) including the capacitor C4 (extends in a location more distant from the display region 5 than the capacitors C1 to C7, which is illustrated in FIG. 2, are) and surrounds the capacitors C1 to C7 and the display region 5.

The EL layer 18 is formed in each pixel PX in the display region 5. The EL layer 18 includes a light-emitting layer that emits light. The second electrode 19 is formed in each pixel PX in the display region 5. The first electrode 16, EL layer 18 and second electrode 19 formed in each pixel PX are referred to as a light-emitting element 40.

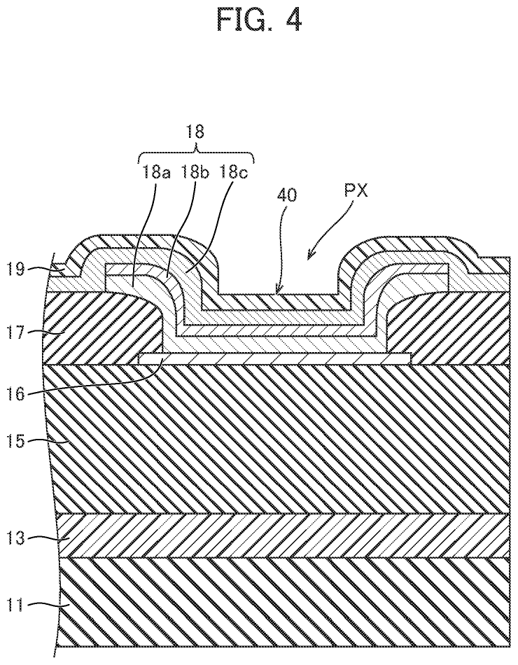

FIG. 4 is a sectional view of the schematic configuration of the light-emitting element 40 of the display device 1 according to the embodiment. The light-emitting element EL layer 18 includes the following: a first charge transport layer 18a formed on the first electrode 16; a light-emitting layer 18b formed on the first charge transport layer 18a; a second charge transport layer 18c formed on the light-emitting layer 18b; and the second electrode 19 formed on the second charge transport layer 18c.

For instance, the light-emitting element 40 emits light through a so-called electroluminescence (EL) method, where the light-emitting layer 18b emits light in response to a current flow between the first electrode 16 and second electrode 19.

The first charge transport layer 18a and the light-emitting layer 18b are layers formed for each pixel PX through, for instance, patterning using a mask, such as evaporation or printing (hereinafter, referred also to as a patterning layer). The second charge transport layer 18c and the second electrode 19 are layers formed continuously throughout the pixels PX. It is noted that the second charge transport layer 18c may be a patterning layer as well formed for each pixel PX through patterning using a mask, such as evaporation or printing.

For instance, the first electrode 16 is an anode, the first charge transport layer 18a is a hole transport layer containing a hole transport material, the second charge transport layer 18c is an electron transport layer containing an electron transport material, and the second electrode 19 is a cathode.

The light-emitting layer 18b is provided between the first charge transport layer 18a and the second charge transport layer 18c, that is, between the first electrode 16 and the second electrode 19. For instance, the light-emitting layer 18b contains an organic red-light-emitting material when provided in the pixel PX that emits red light, the light-emitting layer 18b contains an organic green-light-emitting material when provided in the pixel PX that emits green light, and the light-emitting layer 18b contains an organic blue-light-emitting material when provided in the pixel PX that emits blue light. It is noted that the light-emitting layer 18b may contain quantum dots, which are semiconductor nanoparticles, that emit red light, green light or blue light, instead of these organic light-emitting materials.

The second electrode 19 is a cathode and transparent electrode. The second electrode 19 contains, for instance, a transparent conductive material, such as indium tin oxide (ITO), indium zinc oxide (IZO), zinc oxide (ZnO), aluminum-doped zinc oxide (AZO) or gallium-doped zinc oxide (GZO). For instance, the second electrode 19 is a common electrode provided continuously throughout the light-emitting elements 40.

A hole from the first electrode 16, which is an anode, is transferred into the light-emitting layer 18b by the first charge transport layer 18a, which is a hole transport layer. Further, an electron from the second electrode 19, which is a cathode, is transferred into the light-emitting layer 18b by the second charge transport layer 19c, which is an electron transport layer. Moreover, the hole and electron transferred into the light-emitting layer 18b are recombined together, thus forming an exciton. The formed exciton emits light when undergoing deactivation from an excited state to a ground state. Thus, the light-emitting layer 18b emits colored light, such as red light, green light or blue light.

It is noted that the configuration of the light-emitting element 40 is not limited to the foregoing; the light-emitting element 40 may include other layers. Further, for instance, the first electrode 16 may be a cathode, the first charge transport layer 18a may be an electron transport layer, the second charge transport layer 18c may be a hole transport layer, and the second electrode 19 may be an anode.

As illustrated in FIG. 3, the sealing layer 20 is provided so as to cover the display region and to also cover part of the frame region 6 around the display region 5. For instance, the sealing layer 20 is a multilayer structure including an inorganic layer and an organic layer. For instance, the sealing layer 20 includes the following: a first inorganic sealing layer 21 covering the second electrode 19; an organic layer 22 stacked over the first inorganic sealing layer 21; and a second inorganic sealing layer 23 stacked over the organic layer 22. The sealing layer 20 prevents foreign substances, such as water and oxygen, from permeating the inside of the display device 1.

The first inorganic sealing layer 21 and the second inorganic sealing layer 23 may be each a monolayer structure containing an inorganic insulating material, such as a silicon oxide layer, a silicon nitride layer or a silicon oxide nitride layer, or a multilayer structure with these layers combined. Each of the first inorganic sealing layer 21 and second inorganic sealing layer 23 can be formed through, but not limited to, CVD. The ends of the first inorganic sealing layer 21 and second inorganic sealing layer 23 may be formed beyond the frame-shaped bank 17a and outside the frame-shaped bank 17a (formed in a location more distant from the display region 5 than the frame-shaped bank 17a is).

The organic layer 22 has a flattening effect and is, for instance, a light-transparent resin layer that passes visible light. The organic layer 22 can be composed of an organic material that can be applied, such as acrylic. The organic layer 22 is formed through application, such as ink-jet printing. The organic layer 22 is stopped by the frame-shaped bank 17a. Thus, the end of the organic layer 22 is, for instance, formed along the frame-shaped bank 17a and formed inside the frame-shaped bank 17a (formed in a location closer to the display region 5 than the frame-shaped bank 17a is) or formed so as to overlap the frame-shaped bank 17a in plan view.

As described above, the plurality of capacitors C1 to C7 include the following: the lower electrode 30b1 provided in a relatively lower layer; the upper electrodes 31b1 to 37b1 provided in a relatively upper layer than the lower electrodes 30b1; and the insulating portion 15a provided between the lower electrode 30b1 and the upper electrode 34b1. This can capture electric charge that flows from the frame region 6 into the display region 5, to thus prevent degradation in image's display quality.

For instance, the plurality of capacitors C1 to C7 in this embodiment are provided in a region where the sealing layer 20 is provided. That is, the plurality of capacitors C1 to C7 are layers under the sealing layer 20 and are covered with the sealing layer 20. As described above, providing the plurality of capacitors C1 to C7 close to the pixels PX in the display region 5 to such a degree that these capacitors are covered with the sealing layer 20 enables the plurality of capacitors C1 to C7 to capture, further without fail, electric charge that tries to flow into the thin-film transistors Tr provided in the pixels PX. This can prevent degradation in image's display quality with more certainty.

Furthermore, a portion of the sealing layer 20 covering the plurality of capacitors C1 to C7 (portion overlapping the plurality of capacitors C1 to C7) can also function as part of the charge accumulating unit 3, which accumulates electric charge captured by the plurality of capacitors C1 to C7. That is, the electric charge captured by the plurality of capacitors C1 to C7 can be stored also in the portion of the sealing layer 20 covering the plurality of capacitors C1 to C7 (portion overlapping the plurality of capacitors C1 to C7), without being flowed out in a posterior process step. This enables the amount of electric charge that tries to flow into the thin-film transistors Tr provided in the pixels PX to be detected precisely.

It is noted that the display device 1 may be provided with a function film (not shown) on the sealing layer 20. The function film may have, for instance, at least one of an optical compensation function, a touch sensor function and a protection function.

Further, the display device 1 is a top-emission type for instance, where the display device 1 takes out light emitted by the light-emitting layer 18b toward a side distant away from the support substrate 11 (in FIG. 3 and FIG. 4, above the light-emitting layer 18b), by passing the light through the second charge transfer layer 18c and second electrode 19. Nevertheless, the display device 1 may be a bottom-emission, where the display device 1 takes out light emitted by the light-emitting layer 18b toward the support substrate 11 (in FIG. 3 and FIG. 4, under the light-emitting layer 18b), by passing the light through the first charge transport layer 18, first electrode 16, interlayer insulating layer 15, gate insulating layer 13 and support substrate 11. For a bottom-emission type, the second electrode 19 needs to be composed of a metal reflective layer having high reflectance of visible light, and the first electrode 16 needs to be formed using a transparent conductive layer having high transmittance of visible light.

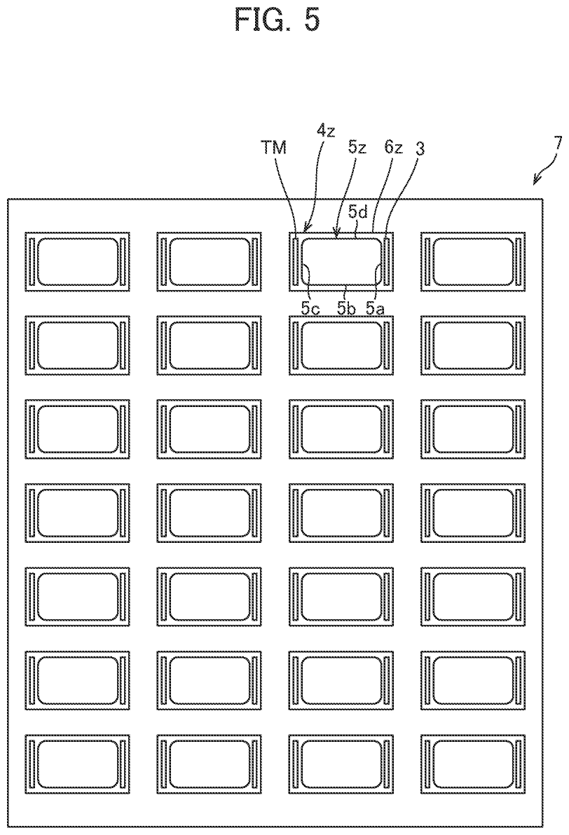

FIG. 5 is a plan view of the configuration of a mother substrate 7 according to the embodiment. The mother substrate 7 is a large-format substrate before the display panel 4 undergoes cut-out in the piece-cut process step and is a substrate undergone process steps that are performed before a process step of forming a patterning layer (e.g., the first charge transport layer 18a and light-emitting layer 18b illustrated in FIG. 4).

For instance, the mother substrate 7 is provided with multiple display-panel formation regions 4z that, when cutting out, constitute the display panels 4 (see FIG. 1). Although the mother substrate 7 is provided with four by seven display-panel formation regions 4z in the example illustrated in FIG. 5, the number of display-panel formation regions 4z that are provided in the mother substrate 7 is non-limiting. Each display-panel formation region 4z includes a display-region formation region 5z that constitutes the display region 5, and a frame-region formation region 6z that constitutes the frame region 6.

The display-region formation region 5z is provided with multiple pixel regions, which are regions that constitute the pixels PX (see FIG. 1), in matrix. Further, in the display-panel formation region 4z is the charge accumulating unit 3 formed along the first side 5a in the display-region formation region 5z, and the terminal section TM formed along the third side 5c in the display-region formation region 5z.

It is noted that the capacitors C1 to C7, connection wires 30b2 to 37b2 and electrode pads 30a to 37a illustrated in FIG. 2, for instance, are formed in the charge accumulating unit 3 on the mother substrate 7. Further, the pixel regions formed in the display-panel formation region 4z are formed in the first electrode 16 to pixel bank 17 in the pixel PX illustrated in FIG. 4, and the first charge transport layer 18a, light-emitting layer 18b, second charge transport layer 18c and second electrode 19, which are to be stacked on the first electrode 16, are not formed.

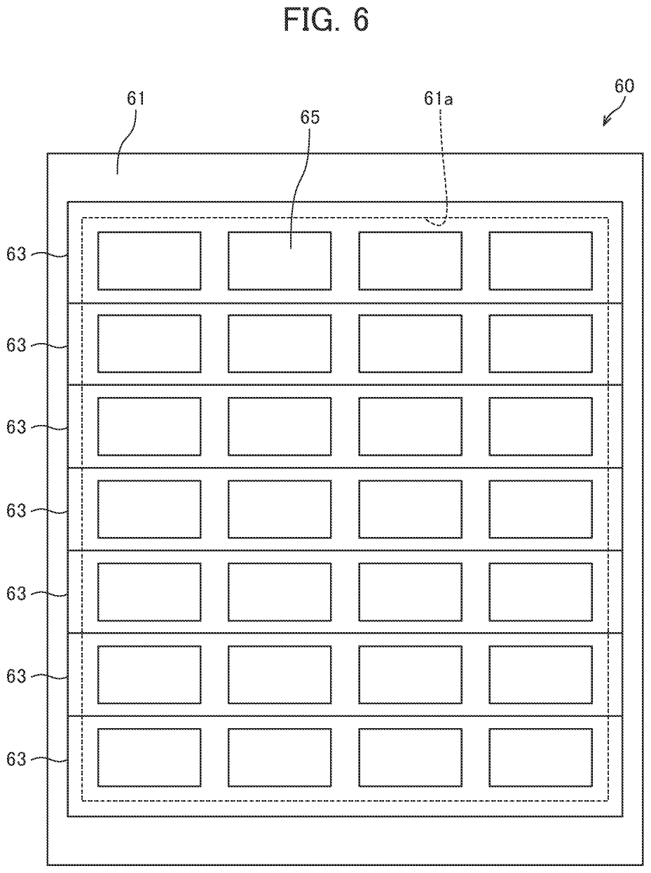

FIG. 6 is a plan view of the schematic configuration of a mask 60 according to the embodiment. The mask 60 is used for patterning any of the patterning layers (e.g., the first charge transport layer 18a and light-emitting layer 18b illustrated in FIG. 4) through a patterning method, such as evaporation. In this embodiment, evaporation is used for instance as the patterning method.

The mask 60 has a frame-shaped frame 61, and multiple mask sheets 63 attached to the frame 61 so as to cover an opening 61a surrounded by the frame 61. The frame 61 and the multiple mask sheets 63 are formed using a metal material. For instance, each mask sheet 63 is a so-called fine-metal mask in the form of a thin sheet. For instance, each mask sheet 63 is fixed to the frame 61 at both ends.

In each mask sheet 63, a mask opening region 65 with multiple mask openings formed is formed in a location that faces the display-region formation regions 5z (see FIG. 5) when the mask sheets 63 are placed so as to face the mother substrate 7. In the mask opening region 65, multiple mask openings are formed in correspondence with, among the plurality of pixels PX provided in the display-region formation region 5z (see FIG. 5), any of the arrangement patterns of pixels PX (red pixels) that emit red light, pixels PX (green pixels) that emit green light, and pixels PX (blue pixels) that emit blue light.

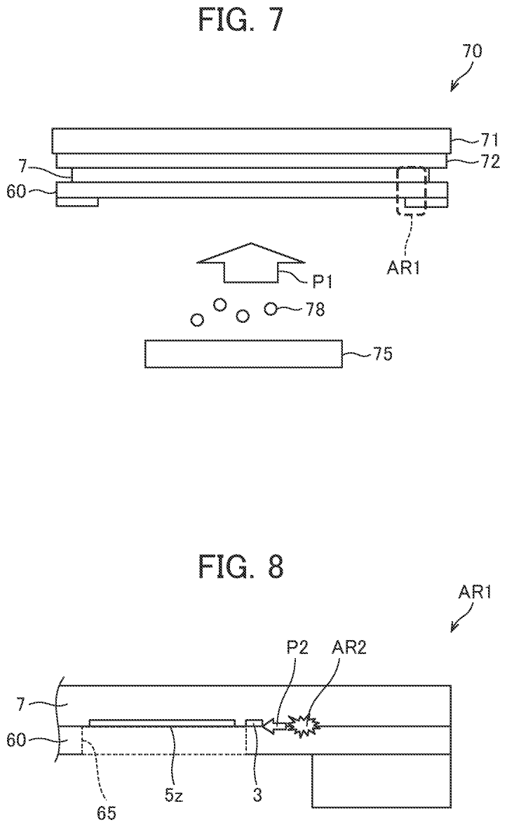

FIG. 7 is a side view of the schematic configuration of an evaporation device 70 according to the embodiment. For instance, the evaporation device 70 includes a magnet plate 71, a touch plate 72, an evaporation source 75, and other components. The magnet plate 71 and the touch plate 72 are substrate supporters supporting the mother substrate 7. The touch plate 72 is a metal plate and sandwiches, together with the mask 60, the mother substrate 7 to thus join the mother substrate 7 and mask 60 together closely. The mask 60 is disposed so as to face the mother substrate 7 on a side opposite to the magnet plate 71 and touch plate 72 with reference to the mother substrate 7.

The evaporation source 75 is provided on a side opposite to the mother substrate 7 with respect to the mask 60 and is spaced from the mask 60. The evaporation source 75 is, for instance, a container made of, but not limited to, ceramic, and having an evaporation hole. The evaporation source 75 houses a patterning material, which is a material that constitutes a patterning layer that is evaporated onto the mother substrate 7.

Upon the mask 60 and mother substrate 7 being set into the evaporation device 70, the magnetic force of the magnet plate 71 attracts the touch plate 72 and mask 60, disposed with the mother substrate 7 interposed therebetween, toward the magnet plate 71. This can prevent a gap between the mask 60 and mother substrate 7 and can prevent pattern blurriness (a phenomenon where a patterning layer is patterned more widely than it should be) in a patterning layer that is patterned onto the mother substrate 7 via the mask 60.

Moreover, evaporation particles 78 passed from the evaporation source 75 through the evaporation hole in a vacuum pass through the multiple mask openings, formed in the mask 60, thus forming a patterning layer in a predetermined pixel region.

As described above, the step of evaporating a patterning layer (patterning step) is performed on a single mother substrate 7 six times in total when the mask 60 and patterning material are replaced to form, for instance, the first charge transport layer 18a in a red pixel, the first charge transport layer 18a in a green pixel and the first charge transport layer 18a in a blue pixel, and to form the light-emitting layer 18b in the red pixel, the light-emitting layer 18b in the green pixel, and the light-emitting layer 18b in the blue pixel.

Here, when evaporation is performed in the evaporation step, the evaporation particles 78 electrically charged attach to the mask 60, thus accumulating electric charge in the mask 60 under evaporation. Further, on a surface of the mask 60 (surface that comes into contact with the mother substrate 7), the evaporation particles 78 attaches, or an evaporation substance transferred from the mother substrate 7 attaches; thus, the surface of the mask 60, which has lower conductivity than it does before the start of the evaporation, is susceptible to charge accumulation.

Moreover, the mask 60 and the mother substrate 7 are brought into close contact with each other in the evaporation step, as earlier described, in order to prevent pattern blurriness in the patterning layer. Moreover, the touch plate 72 and the mask 60 tend to strongly receive the magnetic force of the magnet plate 71 near their ends.

FIG. 8 is a schematic enlarged view of a region AR1 near the ends of the mask 60 and mother substrate 7 illustrated in FIG. 7.

The mask 60 tends to come into contact with the mother substrate 7 near its end due to a stronger magnetic force generated by the magnetic force of the magnet plate 71, and electric charge accumulated in the mask 60 possibly flows into the mother substrate 7. FIG. 8 illustrates an instance where the mask 60 and the mother substrate 7 are in contact with each other in a region AR2, which is located near their ends, due to a stronger magnetic force. The electric charge accumulated in the mask 60 in the region AR2 flows into the mother substrate 7, and the electric charge flowed into the mother substrate 7 flows, as illustrated in an arrow P2, from the region AR2 into the charge accumulating unit 3.

FIG. 9 illustrates the mother substrate 7 under removal from the mask 60 after the evaporation step. As denoted by an arrow P3 illustrated in FIG. 9, the mother substrate 7 possibly becomes charged due to the removal from the mask 60 (removal charge) when the mother substrate 7 undergoes removal from the mask 60 after the evaporation step, and this possibly causes electric charge to accumulate in the mother substrate 7.

Here, for a mother substrate with no charge accumulating units 3 provided, a long-term electric-charge bias is applied to a thin-film transistor formed in a pixel region if electric charge accumulated in the mother substrate flows into the thin-film transistor, and as a result, threshold voltage for switching between ON and OFF of the thin-film transistor shifts (property deficiency of the thin-film transistor), thereby producing an emission smudge and emission unevenness in some of the plurality of light-emitting elements, thereby degrading image's display quality.

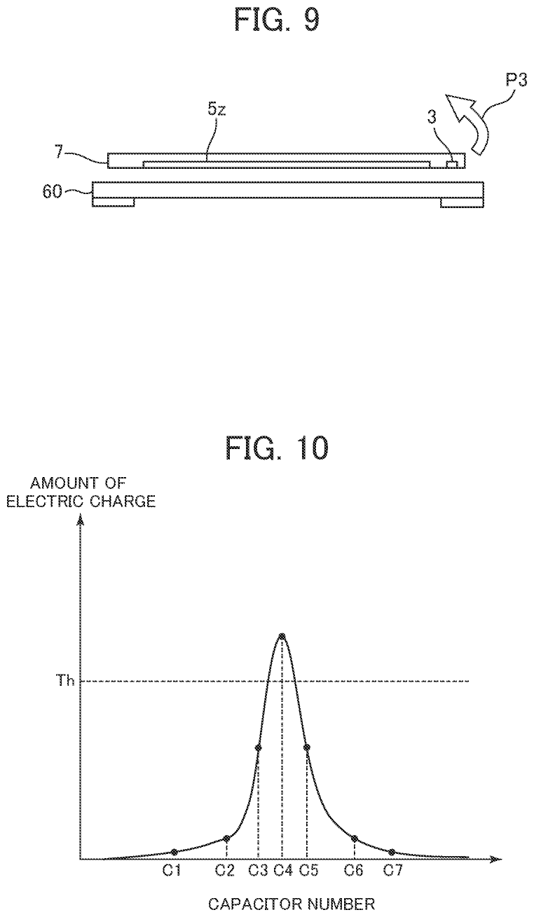

FIG. 10 shows the amount of electric charge accumulated in each of the plurality of capacitors C1 to C7 of the display device 1 according to the embodiment. The lateral axis of the graph illustrated in FIG. 10 indicates a capacitor number with which each of the capacitors C1 to C7 is identified, the longitudinal axis of the same indicates the amount of electric charge accumulated in each of the capacitors C1 to C7.

As earlier described, in the evaporation step illustrated in FIG. 7 through FIG. 9 or other process steps, electric charge possibly flows from the mask 60 into the mother substrate 7, or removal charge occurs during the removal of the mother substrate 7 from the mask 60, thus possibly causing electric charge to flow into the mother substrate 7.

Accordingly, the display device 1 according to the embodiment includes the capacitors C1 to C7, as earlier described. Electric charge can be accumulated in each of the capacitors C1 to C7 individually. Thus, charge flow into the display region 5 can be prevented by accumulating flowed electric charge in each of the capacitors C1 to C7. This can prevent a property deficiency (ON-and-OFF threshold voltage shift) in the thin-film transistor Tr and can thus prevent the display device 1 from degradation in image's display quality.

In addition, the inspection device or operator can identify a location into which electric charge flows easily, by inspecting the amount of electric charge accumulated in the capacitors C1 to C7.

FIG. 10 illustrates an instance where the amount of electric charge accumulated in the capacitors C2 and C6 is larger than that accumulated in the capacitors C1 and C7, where the amount of electric charge accumulated in the capacitors C3 and C5 is larger than that accumulated in the capacitors C2 and C6, and where the amount of electric charge accumulated in the capacitor C4 is larger than that accumulated in the capacitors C3 and C5. Moreover, for instance, the capacitor C4 has electric charge exceeding a predetermined threshold Th, which is an allowable amount of electric charge established in advance.

As described above, the inspection device or operator can identify, by individually inspecting the amount of electric charge accumulated in the capacitors C1 to C7, the location of a capacitor with its amount of electric charge exceeding the predetermined threshold Th, which is an allowable amount, that is, a location into which electric charge flows easily in the display panel 4 illustrated in FIG. 1 (i.e., display-panel formation region 4z illustrated in FIG. 5).

Moreover, when the inspection device or operator identifies the location of a capacitor with its the amount of electric charge accumulated over the predetermined threshold Th, the inspection device or operator eliminates the mother substrate 7 in the process of manufacture from the manufacturing process steps without passing this substrate to the next process step. Consequently, a display device including a thin-film transistor with threshold voltage for switching between ON and OFF being shifted over an allowable range can be prevented from being offered into the market. That is, the display device 1 that can prevent degradation in image's display quality due to flowed electric charge can be achieved.

It is noted that an upper-limit threshold may be established for the integral of the amount of electric charge accumulated in all the capacitors C1 to C7 provided in the charge accumulating unit 3, and that the mother substrate 7 in the process of manufacture may be eliminated from the manufacturing process steps without being passed to the next process step when the integral exceeds the upper-limit threshold. Alternatively, when the integral exceeds the upper-limit threshold, the mother substrate 7 in the process of manufacture may undergo static removal to be a non-defective product, or the mask 60 used may undergo static removal, to reduce the amount of electric charge that flows into the mother substrate 7.

Further, a location into which electric charge flows easily in the mother substrate 7 can be identified by identifying the location of a capacitor with the amount of electric charge exceeding the predetermined threshold Th being accumulated (e.g., the location of the capacitor C4). Accordingly, for instance, the evaporation step may include improving the configuration of the evaporation device 70 so that a location in the mother substrate 7 identified as a location into which electric charge flows easily does not locally contact the mask 60 strongly. This can reduce the amount of electric charge that accumulates in the capacitors C1 to C7 (i.e., the amount of electric charge that accumulates in the mother substrate 7). Consequently, a property deficiency in a thin-film transistor (ON-and-OFF threshold voltage shift) can be prevented to thus improve yield. That is, the display device 1 that can prevent degradation in image's display quality due to flowed electric charge can be achieved.

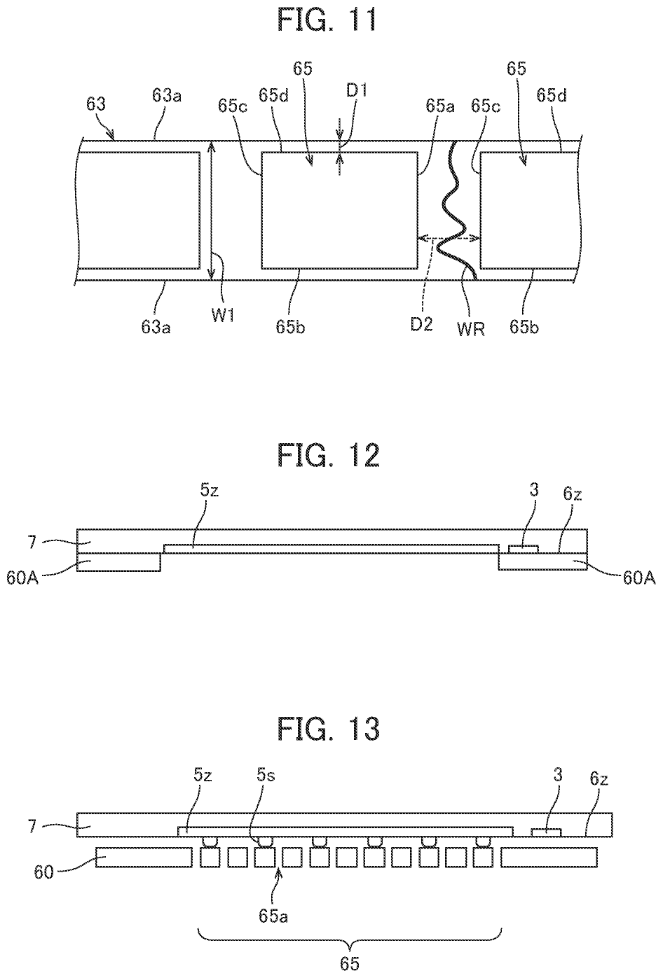

FIG. 11 is an enlarged plan view of part of the mask sheet 63 according to the embodiment. Here, the end of the mask opening region 65 of the mask sheet 63 consists of a first side 65a, a second side 65b, a third side 65c and a fourth side 65d. For instance, the first side 65a and the third side 65c are shorter sides facing each other, and the second side 65b and the fourth side 65d are longer sides facing each other. In the evaporation step, the first side 65a is disposed so as to overlap the first side 5a of the display-region formation region 5z (see FIG. 5) or is disposed near the first side 5a so as to face the first side 5a, the second side 65b is disposed so as to overlap the second side 5b of the display-region formation region 5z (see FIG. 5) or is disposed near the second side 5b so as to face the second side 5b, the third side 65c is disposed so as to overlap the third side 5c of the display-region formation region 5z (see FIG. 5) or is disposed near the third side 5c so as to face the third side 5c, and the fourth side 65d is disposed so as to overlap the fourth side 5d of the display-region formation region 5z (see FIG. 5) or is disposed near the fourth side 5d so as to face the fourth side 5d.

The mask sheet 63 undergoes attachment to the frame 61 (see FIG. 6) through welding or other methods, with its both ends pulled outward in a direction parallel with its longer sides 63a.

Here, the mask sheet 63 is preferably configured such that its width W1, which is the distance between the facing longer sides 63a, is as short as possible in order to improve the accuracy of attachment to the frame 61. Thus, in a region around the mask opening region 65 of the mask sheet 63, a width D2 between the shorter sides of the adjacent mask opening regions 65 facing each other (e.g., distance between the first side 65a of the mask opening region 65 and the third side 65c of the adjacent mask opening region 65) is wider than a distance D1 from the longer sides of the mask opening region 65 (e.g., fourth side 65d) to the longer sides 63a of the mask sheet 63.

That is, in the outside region of the mask opening region 65 of the mask sheet 63, a region along the first side 65a and third side 65c, which are the shorter sides, is larger in area than a region along the second side 65b and fourth side 65d, which are the longer sides. Furthermore, since the difference in pattern between the mask opening region 65 and the region along the first side 65a and third side 65c, which are the shorter sides, is large, a stress tends to concentrate on the mask opening region 65 and the region along the first side 65a and third side 65c, which are the shorter sides, and a wrinkle WR tends to occur. In other words, the mask sheet 63 tends to become wrinkled along the first side 65a and third side 65c, which are the shorter sides of the mask opening region 65.

Moreover, if the wrinkle WR occurs in the mask sheet 63, electric charge concentrates locally on the vertices of the wrinkle WR, where the distance between the mask sheet 63 and mother substrate 7 is minimum, in the evaporation step where the mask sheet 63 and the mother substrate 7 are brought into contact with each other, and electric charge flows easily from this concentrated site into the mother substrate 7. Hence, electric charge flows easily along the shorter sides (the first side 5a and/or third side 5c) of the display-region formation region 5z of the mother substrate 7.

Accordingly, the display device 1 according to this embodiment is configured, as illustrated in FIG. 1, such that the plurality of capacitors C1 to C7 are arranged along a shorter side at the end of the display region 5 (in the example illustrated in FIG. 1, along the first side 5a). As described above, electric charge can be efficiently captured by providing the plurality of capacitors C1 to C7 on the shorter side (in the example illustrated in FIG. 1, the first side 5a), where electric charge flows easily from the mask 60 into the display region 5. As a result, the display device 1 with less display quality degradation can be achieved.

FIG. 12 illustrates the mother substrate 7 under patterning with a common metal mask 60A in the process of manufacturing the display device 1 according to the embodiment. Like the mask 60 described using FIG. 6 and others, the common metal mask (CMM) 60A or an open metal mask (OMM) comes into contact with the frame-region formation region 6z of the mother substrate 7 when the entire display-region formation region 5z undergoes patterning using the so-called common metal mask (CMM) 60A or open metal mask (OMM), both of which have an open region overlapping the entire display-region formation region 5z, rather than using the mask 60, which is used for patterning a patterning layer for each pixel PX. Accordingly, electric charge flows from the common metal mask (CMM) 60A or open metal mask (OMM) into the frame-region formation region 6z.

However, the mother substrate 7 according to this embodiment, which has the charge accumulating unit 3 formed in the frame-region formation region 6z around the display-region formation region 5z, can capture and accumulate flowed electric charge.

FIG. 13 illustrates the mother substrate 7 according to the embodiment with spacers 5s formed, under patterning with the mask 60. For instance, the spacers 5s containing an organic photosensitive insulating material, such as polyimide or acrylic, may be formed on, for instance, the pixel bank 17 on the mother substrate 7. Providing the spacers 5s can avoid a patterning layer on the pixel bank 17 already patterned in the region where pixels are formed, from damage resulting from contact with the mask 60.

However, even when the spacers 5s are provided in the display-region formation region 5z on the mother substrate 7, the magnetic force of the magnet plate 71 (see FIG. 7) brings the mask 60 and the frame-region formation region 6z on the mother substrate 7 into contact with each other, thereby causing electric charge to flow from the mask 60 into the frame-region formation region 6z.

However, the mother substrate 7 according to this embodiment, which has the charge accumulating unit 3 formed in the frame-region formation region 6z around the display-region formation region 5z, can capture and accumulate flowed electric charge.

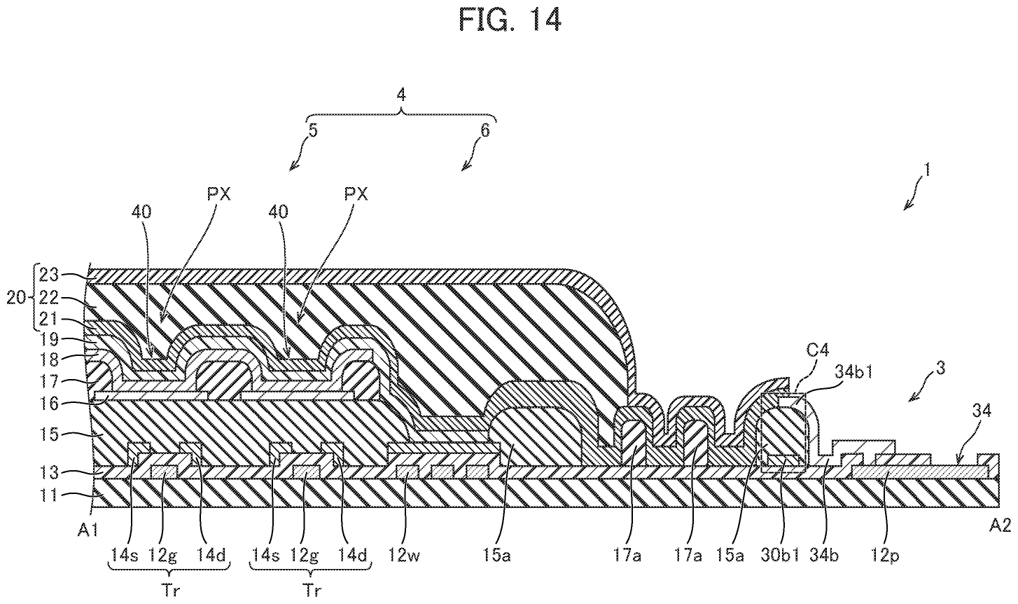

FIG. 14 is a sectional view of the schematic configuration of the display device 1 according to a first modification of the embodiment. FIG. 14 is a sectional view of a modification taken along line A1-A2 in FIG. 2. As illustrated in FIG. 14, the plurality of capacitors C1 to C7 may be provided outside the region where the sealing layer 20 is provided. For instance, the plurality of capacitors C1 to C7 may be provided outside the frame-shaped bank 17a (opposite the display region 5). FIG. 14 illustrates an instance where the capacitor C4 is not covered with the sealing layer 20 and is provided outside the frame-shaped bank 17a. This enables the plurality of capacitors C1 to C7 to capture and accumulate electric charge that flows from the frame region 6 into the display region 5.

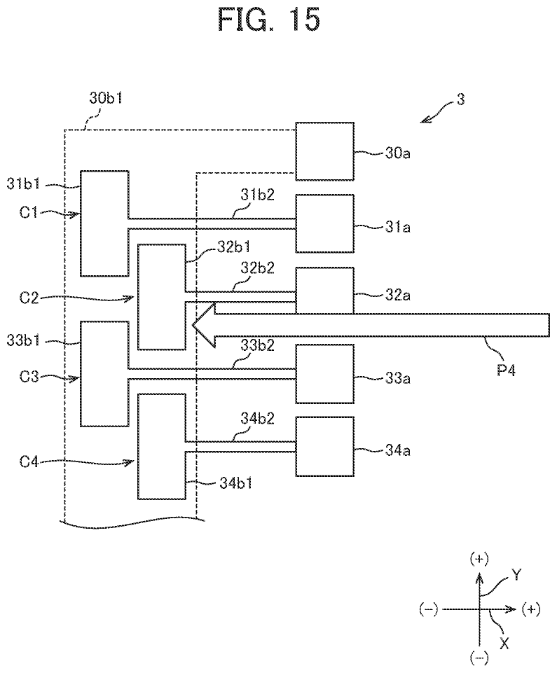

FIG. 15 is a plan view of the display device 1 according to a second modification of the embodiment and schematically illustrates the charge accumulating unit 3 and the display region near the charge accumulating unit 3.

As illustrated in FIG. 15, each of the plurality of capacitors C1 to C7 may be arranged along the end of the display region 5 (at least one of the first side 5a to fourth side 5d) in such a manner that in plan view, these capacitors are partly adjacent to each other in a direction of approach from the frame region 6 to the display region 5 (X-axis minus direction), or in a direction of distance from the frame region 6 (X-axis plus direction).

FIG. 15 illustrates an instance where among the plurality of capacitors C1 to C7, the capacitors C1 to C4 are arranged along the first side 5a of the display region 5. The plurality of capacitors C1 to C7 are arranged in a staggered manner.

The upper electrodes 31b1 to 34b1 of the capacitors C1 to C4 extend in the Y-axis direction so as to respectively intersect with the connection wires 31b2 to 34b2 extending in the X-axis direction. The upper electrodes 31b1 to 34b1 overlap the lower electrode 30b1 and are arranged in the Y-axis direction in a staggered manner.

In other words, the upper electrodes 31b1 to 34b1 (capacitors C1 to C4) are arranged in multiple columns (in the example illustrated in FIG. 15, two columns) in a staggered manner. Furthermore, in other words, the upper electrodes 31b1 to 34b1 (capacitors C1 to C4) are arranged in an overlapping manner without gaps in the direction of approach from the frame region 6 to the display region 5 (X-axis minus direction). The upper electrodes 35b1 to 37b1 (capacitors C5 to C7) are arranged similarly.

Accordingly, electric charge that flows from the frame region 6 into the display region is captured and accumulated by any of the capacitors C to C7 without fail, as denoted by an arrow P4. This can prevent display quality degradation with more certainty.

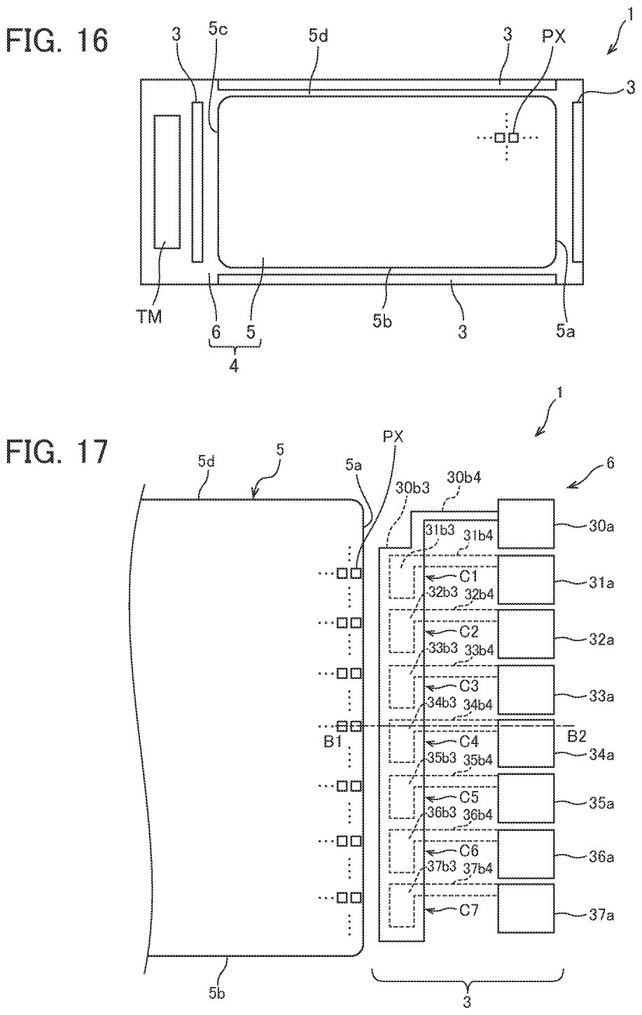

FIG. 16 is a plan view of the schematic configuration of the display device 1 according to a third modification of the embodiment. The display device 1 may include multiple charge accumulating units 3 provided so as to surround the display region 5.

That is, in the display device 1 illustrated in FIG. 16 is the charge accumulating units 3 provided along the respective first side 5a to fourth side 5d of the display region 5. In other words, sets of the capacitors C1 to C7 (see FIG. 2) are arranged along the respective first side 5a to fourth side 5d of the display region 5 so as to surround the display region 5. This enables the multiple charge accumulating units 3 (i.e., multiple sets of the capacitors C1 to C7) to further capture and accumulate electric charge that flows from the frame region 6 into the display region 5.

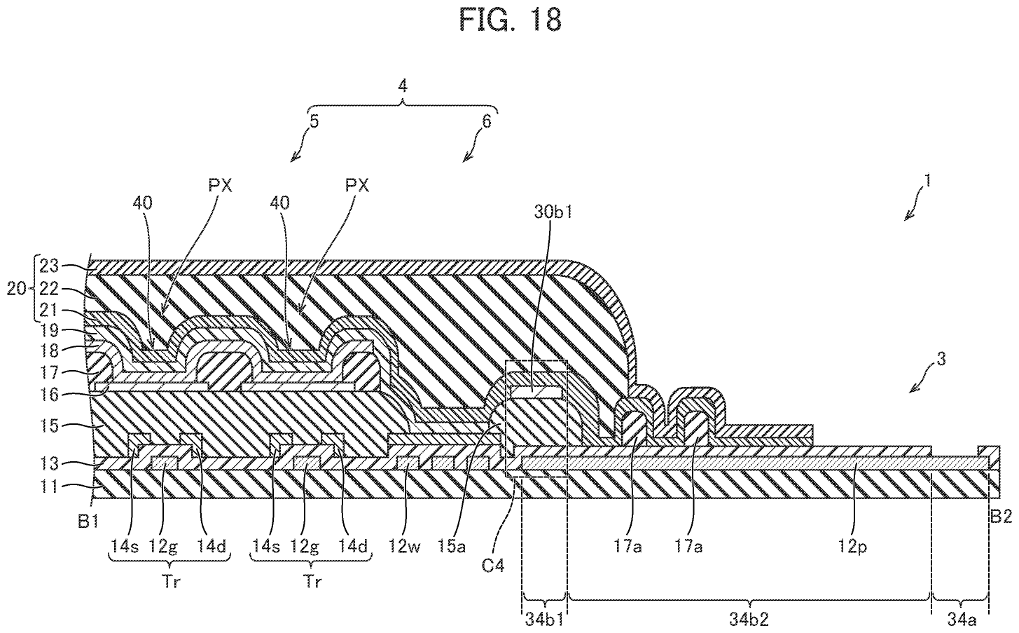

FIG. 17 is a plan view of the schematic configuration of the display device 1 according to a fourth modification of the embodiment. FIG. 18 is a sectional view taken along line B1-B2 in FIG. 17. The capacitors C1 to C7 may be configured such that their upper electrodes and lower electrodes are inverted.

As illustrated in FIG. FIG. 17 and FIG. 18, the capacitor C1 for instance includes the following: a lower electrode (one electrode) 31b3 provided in a relatively lower layer; and an upper electrode (the other electrode) 30b3 provided in a relatively upper layer than the lower electrode 31b3, and overlapping the lower electrode 31b3. The capacitor C2 for instance includes the following: a lower electrode (one electrode) 32b3 provided in a relatively lower layer; and the upper electrode (the other electrode) 30b3 provided in a relatively upper layer than the lower electrode 32b3, and overlapping the lower electrode 32b3. The capacitor C3 for instance includes the following: a lower electrode (one electrode) 33b3 provided in a relatively lower layer; and the upper electrode (the other electrode) 30b3 provided in a relatively upper layer than the lower electrode 33b3, and overlapping the lower electrode 33b3.

The capacitor C4 for instance includes the following: a lower electrode (one electrode) 34b3 provided in a relatively lower layer; and the upper electrode (the other electrode) 30b3 provided in a relatively upper layer than the lower electrode 34b3, and overlapping the lower electrode 34b3. The capacitor C5 for instance includes the following: a lower electrode (one electrode) 35b3 provided in a relatively lower layer; and the upper electrode (the other electrode) 30b3 provided in a relatively upper layer than the lower electrode 35b3, and overlapping the lower electrode 35b3. The capacitor C6 for instance includes the following: a lower electrode (one electrode) 36b3 provided in a relatively lower layer; and the upper electrode (the other electrode) 30b3 provided in a relatively upper layer than the lower electrode 36b3, and overlapping the lower electrode 36b3. The capacitor C7 for instance includes the following: a lower electrode (one electrode) 37b3 provided in a relatively lower layer; and the upper electrode (the other electrode) 30b3 provided in a relatively upper layer than the lower electrode 37b3, and overlapping the lower electrode 37b3.

For instance, the upper electrode 30b3 is a common electrode continuous throughout the plurality of capacitors C1 to C7. The upper electrode 30b3 is connected to the electrode pad 30a via a connection wire 30b4. The connection wire 30b4 has one end connected to the upper electrode 30b3, and the other end connected to the electrode pad 30a.

For instance, the lower electrodes 31b3 to 37b3 are separated away from each other.

The lower electrode 31b3 is connected to the electrode pad 31a via a connection wire 31b4. The connection wire 31b4 has one end connected to the lower electrode 31b3, and the other end connected to the electrode pad 31a. For instance, the lower electrode 31b3 and the connection wire 31b4 contain the same material. The lower electrode 31b3 and the connection wire 31b4 are formed in the same process step using the same material. For instance, the lower electrode 31b3 and the connection wire 31b4 are formed integrally to be thus electrically connected together. The lower electrode 32b3 is connected to the electrode pad 32a via a connection wire 32b4. The connection wire 32b4 has one end connected to the lower electrode 32b3, and the other end connected to the electrode pad 32a. For instance, the lower electrode 32b3 and the connection wire 32b4 contain the same material. The lower electrode 32b3 and the connection wire 32b4 are formed in the same process step using the same material. For instance, the lower electrode 32b3 and the connection wire 32b4 are formed integrally to be thus electrically connected together.

The lower electrode 33b3 is connected to the electrode pad 33a via a connection wire 33b4. The connection wire 33b4 has one end connected to the lower electrode 33b3, and the other end connected to the electrode pad 33a. For instance, the lower electrode 33b3 and the connection wire 33b4 contain the same material. The lower electrode 33b3 and the connection wire 33b4 are formed in the same process step using the same material. For instance, the lower electrode 33b3 and the connection wire 33b4 are formed integrally to be thus electrically connected together. The lower electrode 34b3 is connected to the electrode pad 34a via a connection wire 34b4. The connection wire 34b4 has one end connected to the lower electrode 34b3, and the other end connected to the electrode pad 34a. For instance, the lower electrode 34b3 and the connection wire 34b4 contain the same material. The lower electrode 34b3 and the connection wire 34b4 are formed in the same process step using the same material. For instance, the lower electrode 34b3 and the connection wire 34b4 are formed integrally to be thus electrically connected together.

The lower electrode 35b3 is connected to the electrode pad 35a via a connection wire 35b4. The connection wire 35b4 has one end connected to the lower electrode 35b3, and the other end connected to the electrode pad 35a. For instance, the lower electrode 35b3 and the connection wire 35b4 contain the same material. The lower electrode 35b3 and the connection wire 35b4 are formed in the same process step using the same material. For instance, the lower electrode 35b3 and the connection wire 35b4 are formed integrally to be thus electrically connected together. The lower electrode 36b3 is connected to the electrode pad 36a via a connection wire 36b4. The connection wire 36b4 has one end connected to the lower electrode 36b3, and the other end connected to the electrode pad 36a. For instance, the lower electrode 36b3 and the connection wire 36b4 contain the same material. The lower electrode 36b3 and the connection wire 36b4 are formed in the same process step using the same material. For instance, the lower electrode 36b3 and the connection wire 36b4 are formed integrally to be thus electrically connected together.

The lower electrode 37b3 is connected to the electrode pad 37a via a connection wire 37b4. The connection wire 37b4 has one end connected to the lower electrode 37b3, and the other end connected to the electrode pad 37a. For instance, the lower electrode 3763 and the connection wire 37b4 contain the same material. The lower electrode 37b3 and the connection wire 37b4 are formed in the same process step using the same material. For instance, the lower electrode 37b3 and the connection wire 3764 are formed integrally to be thus electrically connected together.

For instance, the lower electrodes 31b3 to 37b3, each of which is one of the electrodes of a corresponding one of the capacitors C1 to C7, contain the same material and is formed in the same process step as the gate electrode 12g of each of the plurality of thin-film transistors Tr. This eliminates the need to separately add a process step for forming the lower electrode 30b1, which is one of the electrodes of each of the capacitors C1 to C7, and can form the capacitors C1 to C7 without increasing the number of process steps.

Further, for instance, the upper electrode 30b3 of each of the capacitors C1 to C7 contains the same material and is formed in the same process step as the first electrode 16. This eliminates the need to separately add a process step for forming the upper electrode 30b3, which is the other electrode of each of the capacitors C1 to C7, and can form the capacitors C1 to C7 without increasing the number of process steps.

The plurality of capacitors C1 to C7 are a common electrode with their upper electrodes 30b3 are coupled to each other. This can capture, without fail, electric charge that flows from the frame region 6 into the display region 5 when compared with an instance where the lower electrodes are separated from each other with gaps therebetween, and degradation in image's display quality can be thus prevented with more certainty. Further, the plurality of capacitors C1 to C7 are each provided such that the lower electrodes 31b3 to 37b3 are separated away from each other. This enables the plurality of capacitors C1 to C7 to each accumulate electric charge individually, thereby facilitating identifying a location into which electric charge flows easily. Consequently, a property deficiency in the thin-film transistor Tr (see FIG. 3) that drives the pixel PX located near a location into which electric charge flows easily can be avoided easily.

That is, the plurality of capacitors C1 to C7, which have their ends (lower electrodes 31b3 to 37b3) separated from each other, and their other ends (upper electrodes 30b3) coupled together, can capture electric charge without fail and can facilitate identifying a location into which electric charge flows easily.

It is noted that in the display device 1 as well according to the fourth modification of the embodiment, illustrated in FIG. 17, the display panel 4 of the display device 1 may be configured, when cut out of a mother substrate into a piece, such that the electrode pads 30a to 37a are cut away along a cutting line intersecting with each of the connection wires 30b4 to 37b4, to thus no longer exist.

Further, the elements described in the foregoing embodiment and modifications may be combined as appropriate unless otherwise contradicted.

1. A display device comprising:
a display region with a plurality of pixels provided in matrix; a plurality of capacitors provided in a frame region located around the display region, and electrically floating; and
a plurality of thin-film transistors provided for the plurality of respective pixels, wherein
each of the plurality of capacitors includes
a lower electrode provided in a relatively lower layer, an upper electrode provided in a relatively upper layer than the lower electrode, and an insulating portion provided between the lower electrode and the upper electrode,
the lower electrode contains a material identical to a material of a source electrode of each of the plurality of thin-film transistors,
each of the plurality of pixels includes a first electrode, a second electrode, and a light-emitting layer provided between the first electrode and the second electrode, and
the upper electrode contains a material identical to a material of the first electrode.

2. The display device according to claim 1, wherein each of the plurality of capacitors is not connected to and is separated from a routed wire routed from the display region to the frame region.

3. The display device according to claim 1, wherein the plurality of capacitors are arranged along a shorter side at an end of the display region.

4. The display device according to claim 1, wherein the plurality of capacitors are arranged so as to surround the display region.

5. The display device according to claim 1, wherein
each of the plurality of capacitors is arranged along the end of the display region in such a manner that in a plan view, the plurality of capacitors are partly adjacent to each other in a direction of approach from the frame region to the display region, or in a direction of distance from the frame region.

6-8. (canceled)

9. The display device according to claim 1, comprising an interlayer insulating layer covering the plurality of thin-film transistors and having a surface where the first electrode is provided,
wherein the insulating portion contains a material identical to a material of the interlayer insulating layer.

10. The display device according to claim 1, comprising a sealing layer covering the display region,
wherein the plurality of capacitors are provided in a region where the sealing layer is provided.

11. The display device according to claim 1, wherein
the plurality of capacitors are each configured such that the lower electrodes are coupled to each other, and that the upper electrodes are separated from each other, or the plurality of capacitors are each configured such that the lower electrodes are separated from each other, and that the upper electrodes are coupled to each other.

12. The display device according to claim 1, comprising a plurality of electrode pads connected to the plurality of respective capacitors.
